(19) United States
(12) Patent Application Publication
(10) Pub. No.: US 2026/0112892 A1
(43) Pub. Date: Apr. 23, 2026

(54) MONITORING ARRANGEMENT

(71) Applicant: PULSIV LIMITED, Cambridge (GB)

(72) Inventor: Mohammed Zaki Ahmed, Cambridge (GB)

(73) Assignee: PULSIV LIMITED, Cambridge (GB)

(21) Appl. No.: 19/115,868

(22) PCT Filed: Sep. 29, 2023
(86) PCT No.: PCT/GB2023/052519

§ 371 Date: Mar. 27, 2025

(30) Foreign Application Priority Data
Sep. 29, 2022 (GB) 2214326.7

(51) Int. Cl. H02J 3/12; G01R 19/04; G01R 23/16; H02J 3/0014

(52) U.S. Cl. CPC H02J 3/12; G01R 19/04; G01R 23/16; H02J 3/0014

(57) ABSTRACT

A monitoring arrangement for monitoring a parameter value associated with an AC supply or an AC component of a supply in a distribution network. The monitoring arrangement includes a sensor arrangement electrically connected, in use, to the network or otherwise monitoring the network, and a control unit operable to use the output of the sensor arrangement to determine, for a voltage, an amplitude value for a selected frequency. The method allows the operation of the device to be controlled depending on the supply from the network, without relying on signal components from rotating power converters.

### FIELD OF THE INVENTION

The present invention relates to a monitoring arrangement, in particular to a monitoring arrangement for monitoring the status of a generator or power supply such as a power converter, battery or power bank. More specifically, the present invention relates to an arrangement for in-line monitoring the status of a generator or supply for an electrical distribution network, to be able to use information about the status for controlling the operation of a load or device.

### BACKGROUND

Energy supply via an electrical distribution network, or power grid, is subject to fluctuations due to periods of higher or lower demand. This results in typically higher demand during peak times such as morning peak times or evening peak times.

Different methods are being developed to allow the power demand to be measured to thereby control operation of devices depending on the status of power supplies and generators. For instance, in many scenarios it may be tolerable or even unnoticeable if energy use is delayed, or temporarily reduced, such as for instance for washing machine heating or electrical device charging. Therefore, such loads may be reduced and/or delayed during periods of peak demand, to be resumed in off-peak periods.

One method considered by the present inventor involves analysing frequency fluctuations in an AC signal or AC component of a voltage signal at a device, to derive from the fluctuations whether or not there is excess supply or a high demand. This is based on the appreciation that many types of energy supply use rotating generators, such as turbines. In that case, a change in frequency of rotation can be measured as a frequency fluctuation in the voltage supplied to a device. An increased frequency can be related to an increased supply and a lower frequency can be related to a lower supply or, respectively, relatively higher demand. The method is less practical for power supplies avoiding rotational energy generation. For instance, voltage source converters or inverters such as batteries or power banks may operate to provide AC voltage of a practically constant sine waveform, with little frequency fluctuation.

The present invention seeks to provide an alternative to, or extension to, known methods by reducing or entirely avoiding reliance on the presence of periodic signals indicative of fluctuations of rotating power generators.

### SUMMARY OF THE INVENTION

In accordance with a first aspect of the invention, there is provided a monitoring arrangement as defined in claim 1, for monitoring a parameter value associated with an AC supply or an AC component of a supply in a distribution network, the monitoring arrangement comprising a sensor arrangement electrically connected, in use, to the network or otherwise monitoring the network, and a control unit operable to use the output of the sensor arrangement to determine, for a voltage, an amplitude value for a selected frequency.

In some embodiments, the control unit is configured to determine the amplitude value of the signal at a predetermined frequency.

The amplitude value may be determined, for instance, via spectral analysis of the voltage signal to extract a component at a particular frequency, e.g. 50 Hz.

In some embodiments, the predetermined frequency is a frequency value in the region between 45 Hz and 55 Hz, preferably 50 Hz.

The frequency value may be higher than 46, 47, 48, or 49 Hz. The frequency value may be lower than 54, 53, 52, or 51 Hz.

In some embodiments, the predetermined frequency is a frequency value in the region between 55 Hz and 65 Hz, preferably 60 Hz.

The frequency value may be higher than 56, 57, 58, or 59 Hz. The frequency value may be lower than 64, 63, 62, or 61 Hz.

In some embodiments, the arrangement is configured to derive the amplitude value from input values from a waveform region without peak values of a monitored waveform.

In some embodiments, the arrangement is configured to determine data points representative of at least two slopes of a waveform, to determine an intersection between two slopes, and to interpret the intersection of the slopes as the amplitude value.

The waveform may be the waveform component of the signal at the predetermined frequency.

In some embodiments, the arrangement is configured to carry out spectral analysis of the waveform to thereby derive the amplitude value.

As will be appreciated, spectral analysis of the waveform may allow, for instance, the shape of a pure sine wave to be determined that may have a different amplitude value than a measured waveform.

In some embodiments, the control unit uses a recursive discrete Fourier transform (DFT) based technique in analysing the AC signal or waveform of a predetermined wavelength of it, to thereby derive the amplitude value.

In some embodiments, the control unit uses a fast Fourier transform (FFT) based technique in analysing the AC signal or waveform of a predetermined wavelength of it, to thereby derive the amplitude value.

In some embodiments, the control unit uses a fast sine transform (FST) based technique in analysing the AC signal or waveform of a predetermined wavelength of it, to thereby derive the amplitude value.

In some embodiments, the control unit uses a fast cosine transform (FCT) based technique in analysing the AC signal or waveform of a predetermined wavelength of it, to thereby derive the amplitude value.

In some embodiments, the arrangement is configured to control the operation of an electrical device, an electrical storage device, a smart electrical device, and/or of an electrical heating device such as a storage heater or water heater.

The arrangement may be used to control the charging or use of a battery or powerbank.

In some embodiments, the arrangement is configured to determine two or more successive calculated amplitude values, and to derive from a change between successive calculated amplitude values a change in supply available in the distribution network.

In some embodiments, the control unit is configured to interpret a value indicative of an increase of the amplitude value as indicative of an increased supply from the distribution network.

In some embodiments, the control unit is configured to interpret a value indicative of a decrease of the amplitude value as indicative of excess demand from the distribution network.

In some embodiments, the arrangement is configured to determine a difference between the amplitude value and a measured amplitude value, and to using the difference to derive an efficiency value indicative of losses in the distribution network.

In some embodiments, the control unit is configured to interpret an increase in efficiency as indicative of an increased supply from the distribution network, and/or to interpret a decrease of the amplitude value as indicative of excess demand from the distribution network.

In accordance with a second aspect of the invention, there is provided a method as defined in claim 18, for monitoring a parameter value associated with an AC supply or an AC component of a supply in a distribution network, the method comprising using a sensor arrangement electrically connected to the network or otherwise monitoring the network, determining, using an output of the sensor arrangement, an amplitude value for a selected frequency, and controlling an operation of a load or of a device based on a change between successive amplitude values.

In some embodiments, the method comprises using the sensor arrangement to determine an amplitude value at a frequency value in a region between 45 Hz and 55 Hz and/or a region between 55 Hz and 65 Hz.

The frequency value may be 50 or 60 Hz, respectively.

In some embodiments, the arrangement is configured to derive the amplitude value from input values from a waveform region without peak values of a monitored waveform.

In some embodiments, the method comprises determining data points representative of at least two slopes of a waveform, determining an intersection between two slopes, and interpreting the intersection as the amplitude value.

In some embodiments, the method comprises using spectral analysis of the waveform to thereby derive the amplitude value.

In some embodiments, the method comprises controlling operation of an electrical device, an electrical storage device, a smart electrical device, and/or of an electrical heating device such as a storage heater or water heater.

In some embodiments, the method comprises repeatedly determining the amplitude value, and to derive from a change in amplitude value a change in supply available in the distribution network.

Any one or more of the embodiments described in relation to the first aspect may be combined with any one or more embodiments described in relation to the second aspect. Any one or more of the embodiments of the second aspect may comprise one or more steps using a configuration of any one or more of the embodiments of the first aspect.

### DESCRIPTION OF THE FIGURES

Exemplary embodiments of the invention will now be described with reference to the Figures, in which:

FIG. 1 is a schematic graph of a grid monitoring arrangement;

FIG. 2 is an illustration of an exemplary waveform to illustrate the invention; and

FIG. 3 is a flow diagram showing exemplary steps of a method of operating a device.

### DESCRIPTION

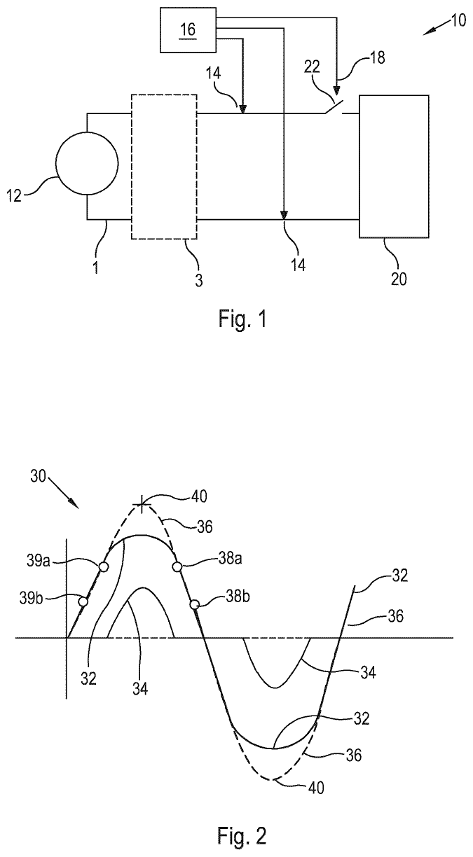

FIG. 1 shows a schematic arrangement of monitoring system 10 for a network grid 1 providing a supply of power from a generator, or source 12, for a load such as a device 20 connected to the grid 1 to be powered or charged via the grid 1. The monitoring system 10 includes a control arrangement 16 comprising one or more sensors 14, constituting a sensor arrangement, to measure or record the magnitude of a signal, such as the magnitude of a voltage, and to provide an output of the sensor 14 as a sensor measurement as an input to a control unit 16. The sensors 14 may be connected to the network grid 1, or otherwise arranged to monitor the output of the network grid 1. Suitable sensor or meter arrangements capable of recording a voltage signal will be known to a skilled person and are not discussed in detail herein.

While the device 20, the control unit 16 and the sensors 14 are illustrated separately in FIG. 1, it will be appreciated that one or more sensors 14 and/or a control unit 16 may be a component of the device 20. For instance, they may be provided as components on a printed circuit board. Alternatively or in addition, one or more sensors 14 and/or the control unit 16 may be a separate device configured to communicate with the device 20. Suitable communication protocols for wireless or wired communication are known and will not be described in detail herein. Likewise, multiple control units 16 may be arranged to influence the operation of one or more common devices 20, and/or one or more devices 20 may be controlled by a one or more common control units 16.

The control unit 16 is configured to control operation of the device 20, for instance by controlling operation of a switch 22 in response to output from one or more sensors 14.

The switch 22 should be understood as an illustrative example of a configuration allowing the control unit 16 to operate the device 20 in one of two or more different modes of operation. Some types of device 20 may be operated without actuation of a physical switch. Several methods of controlling the operation of a device 20 will be known to a person skilled in the art and will not be discussed in detail herein. Instead of controlling operation of a switch 22, the control unit 16 may operate the device 20 in one of several modes, such as to switch between a higher-performance mode and a lower-performance mode, or so as to switch between a faster-charging mode and a lower-charging mode, etc.

The monitoring arrangement 10 is configured to analyse the signal from the electrical grid 1 and to determine, for a predetermined voltage wavelength, an amplitude voltage value representative of the amplitude of the voltage signal. The wavelength may be selected by an appropriate wavelength filter. For instance, the waveform at a pre-determined wavelength may be selected using a Fourier Transform technique, for instance to extract a sine waveform component of a voltage signal at 50 Hz or other wavelength. The invention is thought to be useful for wavelengths of 50 Hz or 60 Hz, each being a fundamental wavelength of electrical distribution networks in Europe and North America, respectively. However, the invention is not necessarily limited to a specific wavelength and may be used with a different reference wavelength. It will be appreciated that a decrease in voltage, for instance measuring 48 Hz instead of expected nominal 50 Hz, or measuring 58 Hz instead of expected nominal 60 Hz, is indicative of excess demand in relation to the supply from the source 12.

It was an appreciation underlying the present invention that the voltage amplitude, if measured directly from the AC voltage signal at the device 20, may be lower than a voltage signal amplitude measured at the source 12. This will be understood to be the case due to losses 3 (here: indicated by a dashed-line rectangle) in the grid 1 due to transmission inefficiencies along power lines and transmission equipment between the source 12 and the device 20, as well as due to unknown influences and other effects such as a fluctuating number of other loads being connected and/or disconnected. For the purpose of this disclosure it is assumed that the losses 3 may be difficult to quantify.

With reference to FIG. 2, a graph 30 illustrates waveforms that may be obtained by measurement of a voltage amplitude. It will be appreciated that the graph illustrates a full period AC waveform at a single wavelength, and may be representative of a 50 Hz waveform or a 60 Hz waveform, as may have been obtained after analysis of a measured voltage signal. In the absence of losses, a perfect or near-perfect sine waveform 36 would be expected to be obtained via a measurement, after extracting a waveform at a predetermined wavelength such as 50 Hz, with a loss-free amplitude peak 40.

However, due to the existence of losses 3 (see FIG. 1), indicated by a loss waveform 34, a real waveform may have a “flatter” shape in the form of an actual waveform 32. The actual waveform 32 may be considered as a difference between a sine, loss-free waveform 36 and the loss waveform 34. Without separate measurement directly at the source 12, measuring only the actual AC voltage at the device 20, the shape of the loss waveform 34 may be unknown, and thus the magnitude of the losses 3 may be unknown, and as such the loss-free amplitude peak 40 of the loss-free waveform 36 may not be measurable by a direct AC voltage measurement near the device 20.

If the magnitude of the losses 3 is not known or cannot be derived with a required accuracy, and or cannot be determined with sufficient temporal resolution, then it will be appreciated that the magnitude of the sine waveform 36 can practically not be determined from a measurement of the waveform 32 at the device 20.

As such, while measuring the amplitude of the waveform 32 may be of interest in certain scenarios, this may result in measuring amplitude fluctuations that may be influenced by fluctuating grid losses 3 rather than, or in addition to, the amplitude that would be expected to be measured at the source 1.

To be able to determine an amplitude value, the present disclosure suggests measuring the slopes of the waveform 32, i.e. one rising slope and one falling slope, by measuring multiple points 38a, 38b (here: two points falling on a decreasing slope) and 39a, 39b (here: two points on a rising slope), and determining the intersection of two adjacent slopes (i.e. an upward and a downward slope) as an amplitude value location indicative of a loss-free amplitude peak 40, i.e. an amplitude value of the waveform expected if measured in the absence of losses. This allows using the calculated amplitude value as value indicative of a loss-free amplitude value that would be expected from a measurement directly at the source 1. The location of the points 38a, 38b, 39a, 39b, may be determined dynamically with reference to the actual waveform 32 peak and/or with reference to the baseline, e.g. at 30% and 50% of the actual waveform 32 amplitude, or other suitable values. For a sine waveform, a region of about 35-50% of the amplitude can be assumed to lie within a relatively linear region of a sine waveform. In this region, the points on the sine wave are closer to the base and removed from the peak, and therefore less likely to be affected from peak flattening or other loss effects.

The calculation of the loss-free, calculated amplitude value can be carried out via effectively as few as five calculation steps, namely two steps for determining two data points 39b, 39a for one slope, two steps for determining two data points 38a, 38b for a return slope, and a fifth calculation step for calculating the intersection 40 of the two slopes. It will be appreciated that reliance on fewer calculation steps allows more calculations of the loss-free amplitude to be made in a given period of time, and therefore allows the temporal resolution of such measurements to be increased.

In scenarios in which it can be assumed that the wave signal is symmetric, the calculation effort can be reduced further. If it is appreciated that the position of two slope data points 38a, 38b is symmetric to the data points 39a, 39b, the calculation may be reduced to two steps for determining two data points (e.g. 38a, 38b), and determining the intersection 40 from the data points 38a, 38b and their correspondingly mirrored/inverted values.

Alternatively or in addition, the waveform may be processed by spectral analysis, to determine the peak amplitude of a pure sine wave at a given wavelength, e.g. 50 Hz or 60 Hz, as will be appreciated. While the use of two data points may mathematically provide multiple possible results, it will be appreciated that comparison with an expected wavelength, e.g. 50 Hz and/or comparison with successive measurements, will allow an unambiguous value to be determined. Suitable spectral analysis methods will be known, and include recursive discrete Fourier transform (DFT), fast Fourier transform (FFT), fast sine transform (FST), fast cosine transform (FCT) and other suitable techniques.

As set out above, since an underlying waveform can be assumed to follow a sine curve, regularly sampling the measurable waveform 32 allows data points to be determined from a region removed from the peak, using data points closer to the base, approximately in a region of about 30% to 50% of the peak amplitude. As one example, a linear region of a sine wave may be derived from a first order approximation from a Taylor series expansion, where the first order expansion is linear. Other suitable methods may be used depending on the level of accuracy desired. In this manner, spectral analysis can be used instead of, or in addition to, geometric analysis. In other words, spectral analysis may be carried out using, as input, data from a region removed from the peak amplitude, typically in a region of around 30 to 50% of a peak amplitude, and typically in a linear or in a near-linear region of a sine waveform function, to calculate the amplitude value representative of a loss-free peak amplitude. This avoids a need to use data points from the measured peak amplitude.

By measuring and comparing successive amplitude values that are calculated and representative of a loss-free amplitude, the arrangement allows an arrangement of sensors 14 near, at, or inside, the device 20 to be used to determine fluctuations in voltage amplitude at the source 1. It will be appreciated that the monitoring system may obtain measurements in regular intervals. The regular intervals may be several hundred or thousand times per second, or smaller or larger intervals, such as once every minute or once every few minutes, e.g. in five minutes intervals. It will be appreciated that this provides a correspondingly high temporal resolution for determining fluctuations in supply and demand, and therefore allows the operation of the device 20 to be controlled in short intervals.

By comparing a voltage amplitude value with one or more preceding loss-free amplitude peaks 40, a determination can be made whether or not there is an increase in voltage amplitude, or a decrease in voltage amplitude. Furthermore, voltage amplitude performance over time may be determined. This may allow the voltage amplitude to be mapped to a time of a day, to a weekday, to a time of each weekday, etc.

Alternatively or in addition, the monitoring system 10 may comprise a configuration allowing it to measure an efficiency value, or loss value, respectively, as a difference between the loss-free, calculated voltage amplitude and the actual, measured voltage amplitude. The efficiency value, or loss value can be understood as indicative of losses in the distribution network. The monitoring system 10 may comprise a configuration allowing it to determine whether or not the losses 3 are increasing or decreasing, for instance by comparing a change in successive efficiency values or loss values.

Alternatively or in addition, the monitoring system 10 may compare the loss-free amplitude values in relation to the loss values. The monitoring system 10 may derive a loss ratio as a ratio between loss values and calculated (loss-free) voltage amplitude. The monitoring system 10 may comprise a configuration allowing it to determine whether or not the loss ratio is increasing or decreasing, for instance by comparing a change in successive loss ratio values.

If the loss-free voltage amplitude increases, this may be interpreted as indicative of an excess supply. If the loss-free voltage amplitude is decreased, this may be interpreted as higher demand placed on the source 12. The control unit 16 may control the operation of the device 20 depending on the determination made by the control unit 20 about the status of the source 12.

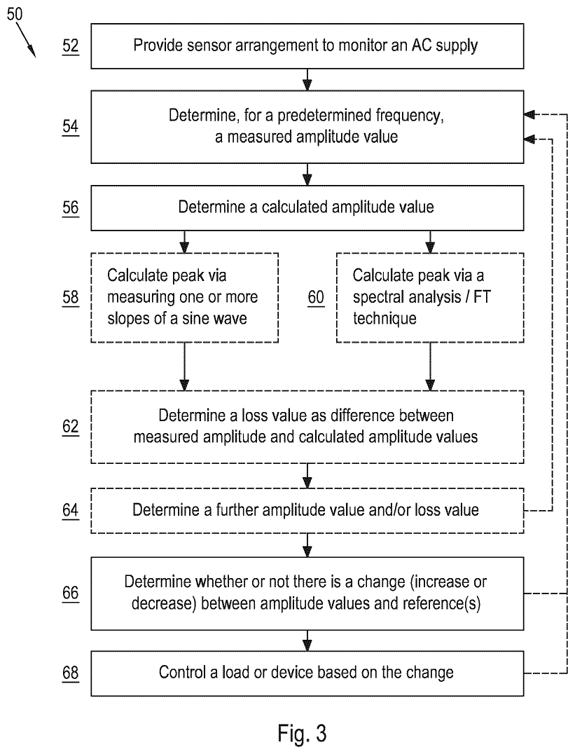

Turning to FIG. 3, this shows exemplary steps of a method 50 for monitoring a parameter value associated with an AC supply in a distribution network. The parameter may be a value representative of a loss-free amplitude, or peak value, of an AC signal. In step 52, a sensor arrangement is provided to monitor an AC signal in a distribution network. The sensor arrangement may be configured to determine the waveform of an AC signal at a pre-determined wavelength, e.g. at 50 Hz or at 60 Hz. In an optional step 54, the method is used to determine the amplitude of the measured AC signal or of the waveform at a predetermined wavelength. It will be appreciated that, in the absence of further information, the amplitude of the measured AC signal may be lower than a loss-free amplitude that the signal will be expected to have in the absence of losses. In step 56, a calculated amplitude value is determined. The calculated amplitude value may be considered as indicative of a loss-free amplitude value. Step 56 may include, or be provided by, a step 58 in which the loss-free amplitude value is determined on the basis of an intersection between two slopes, in the manner described above in relation to FIG. 2. Step 56 may include, or be provided by, a step 60 in which the loss-free amplitude value is determined using spectral analysis, such as a Fourier Transform based technique, which may be a discrete Fourier transform (DFT), fast Fourier transform (FFT), fast sine transform (FST) fast cosine transform (FCT) or other suitable technique. Steps 58 and 60 may be carried out concurrently or sequentially, or only one of steps 58 and 60 may be carried out. The input for steps 58 and/or 60 may be a waveform region removed from the peak amplitude of the measured AC signal, e.g. taken from a linear region of a sine waveform. In an optional step 62, a loss value may be determined as a difference between a measured amplitude value, such as may have been obtained in optional step 54, and the calculated amplitude value as obtained in step 56, 58 and/or 60. In step 64, a further calculated amplitude value is determined, and/or a further loss value is determined. In step 66, successive calculated amplitude values are compared against a reference value. The reference value may be a baseline reference, e.g. a baseline value of zero, or one or more preceding calculated amplitude values. In step 66, determination is made whether a change between calculated amplitude values and/or loss values is positive or negative, i.e. whether it is indicative of an increase in peak amplitude or a decrease in peak amplitude, and/or whether it is indicative of an increase in loss value or a decrease in loss value.

In step 68, an operation of a load or of a device is controlled based on the change determined in step 66. By way of example, in step 68 an operation may be controlled of an electrical storage device, battery and/or powerbank, or of a smart electrical device, or of an electrical heating device such as a storage heater or water heater.

Although a specific embodiment of the invention is described herein, it will be appreciated that a wide range of modifications or alterations may be made thereto without departing from the scope of the invention as defined by the appended claims.

1. A monitoring arrangement for determining a voltage amplitude of a supply AC signal of an AC supply or an AC component of a supply in a distribution network, the monitoring arrangement comprising:
a sensor arrangement electrically connected, in use, to a load, the load being connected, in use, across the AC supply, or the supply, of the distribution network to receive a load AC signal from the distribution network, the load AC signal having a different voltage amplitude to the voltage amplitude of the supply AC signal due to losses in the distribution network,
wherein the sensor arrangement is configured to measure voltage values of the load AC signal; and
a control unit operable to use the voltage values measured by the sensor arrangement to determine a value indicative of the voltage amplitude of the supply AC signal for a selected frequency.

2. The arrangement according to claim 1, wherein the control unit is configured to determine the value indicative of the voltage amplitude of the supply AC signal at a predetermined frequency.

3. The arrangement according to claim 2, wherein the predetermined frequency is a frequency value in a region between 45 Hz and 55 Hz, preferably 50 Hz; or
wherein the predetermined frequency is a frequency value in a region between 55 Hz and 65 Hz, preferably 60 H.

4. (canceled)

5. The arrangement according to claim 1, configured to determine the value indicative of the voltage amplitude of the AC supply signal based on voltage values in a linear region of a waveform of the measured load AC signal.

6. The arrangement according to claim 1, configured to determine data points representative of at least two slopes of a waveform of the measured load AC signal, to determine an intersection between two slopes, and to interpret the intersection of the slopes as the value indicative of the voltage amplitude of the supply AC signal for the selected frequency.

7. The arrangement according to claim 1, configured to carry out spectral analysis of a waveform of the measured load AC signal to thereby derive the value indicative of the voltage amplitude of the supply AC signal for the selected frequency.

8. The arrangement according to claim 1, wherein the control unit uses a recursive discrete Fourier transform, DFT, based technique in analysing the load AC signal or waveform of a predetermined wavelength of the load AC signal, to thereby derive the value indicative of the voltage amplitude of the supply AC signal for the selected frequency.

9. The arrangement according to claim 1, wherein the control unit uses a fast Fourier transform, FFT, based technique in analysing the load AC signal or a waveform of a predetermined wavelength of the load AC signal, to thereby derive the value indicative of the voltage amplitude of the supply AC signal for the selected frequency; or
wherein the control unit uses a fast sine transform, FST, based technique in analysing the load AC signal or a waveform of a predetermined wavelength of the load AC signal, to thereby derive the value indicative of the voltage amplitude of the supply AC signal for the selected frequency; or
wherein the control unit uses a fast cosine transform, FCT, based technique in analysing the load AC signal or a waveform of a predetermined wavelength of the load AC signal, to thereby derive the value indicative of the voltage amplitude the supply AC signal for the selected frequency.

10. (canceled)

11. (canceled)

12. The arrangement according to claim 1, configured to control operation of the load, wherein the load is one of: an electrical device, an electrical storage device, a smart electrical device, and/or of an electrical heating device such as a storage heater or water heater.

13. The arrangement according to claim 1, configured to continually determine two or more successive calculated values indicative of voltage amplitudes of the supply AC signal, and to derive, from a change between successive calculated values indicative of the voltage amplitudes of the supply AC signal, a change in supply available in the distribution network.

14. The arrangement according to claim 1, wherein the control unit is configured to interpret a value indicative of an increase of the value indicative of the voltage amplitude of the supply AC signal as indicative of an increased supply from the distribution network; and/or
wherein the control unit is configured to interpret a value indicative of a decrease of the value indicative of the voltage amplitude of the supply AC signal as indicative of excess demand from the distribution network.

15. (canceled)

16. The arrangement according to claim 1, configured to determine a difference between the determined value indicative of the voltage amplitude of the supply AC signal, and a measured voltage amplitude of the AC signal, and use the difference to derive an efficiency value indicative of losses in the distribution network.

17. The arrangement according to claim 16, wherein the control unit is configured to interpret an increase in efficiency value as indicative of an increased supply from the distribution network, and/or to interpret a decrease of the determined value indicative of the voltage amplitude of the supply AC signal as indicative of excess demand from the distribution network

18. A method of determining a voltage amplitude of a supply AC signal of an AC supply or an AC component of a supply in a distribution network, the method comprising:
using a sensor arrangement electrically connected to a load, the load being connected across the AC supply or supply of the distribution network to receive a load AC signal from the distribution network, the load AC signal having a different voltage amplitude to the voltage amplitude network of the supply AC signal due to losses in the distribution network,
wherein using the sensor arrangement comprises measuring voltage values of the load AC signal;
determining, using of the measured voltage values output by the sensor arrangement, a value indicative of the voltage amplitude of the supply AC signal for a selected frequency; and
controlling an operation of the load based on a change between successive determined voltage amplitudes.

19. The method according to claim 18, comprising using the sensor arrangement to determine the value indicative of the voltage amplitude at a frequency value in a region between 45 Hz and 55 Hz and/or a region between 55 Hz and 65 Hz, preferably 50 Hz or 60 Hz, respectively.

20. The method according to claim 18, wherein determining the value indicative of the voltage amplitude of the supply AC signal for the selected frequency is based on voltage values in a linear region of a waveform of the measured load AC signal.

21. The method according to claim 18, comprising:
determining data points representative of at least two slopes of a waveform,-of the measured load AC signal: and
determining an intersection between two slopes, and interpreting the intersection as the value indicative of the voltage amplitude of the supply AC signal for the selected frequency.

22. The method according to claim 18, comprising using spectral analysis of a waveform of the measured load AC signal to thereby derive the value indicative of the voltage amplitude of the supply AC signal for the selected frequency.

23. The method according to claim 18, wherein the load is one of: an electrical device, an electrical storage device, a smart electrical device, and/or of an electrical heating device such as a storage heater or water heater.

24. The method according to claim 18, comprising:
repeatedly determining the value indicative of the voltage amplitude of the supply AC signal; and
deriving, from a change in the value indicative of the voltage amplitude of the AC supply signal, a change in supply available in the distribution network.
